(19) United States
(12) Patent Application Publication
(10) Pub. No.: US 2008/0039024 A1
(43) Pub. Date: Feb. 14, 2008

(54) Amplifying Circuit, Radio Communication Circuit, Radio Base Station Device and Radio Terminal Device

(75) Inventors: Kazuhiko Ikeda, Ishikawa (JP); Takashi Izumi, Ishikawa (JP); Takashi Enoki, Kanagawa (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., OSAKA (JP)

(21) Appl. No.: 11/718,968

(22) PCT Filed: Nov. 8, 2005
(86) PCT No.: PCT/JP05/20438

§ 371 Date: May 9, 2007

(30) Foreign Application Priority Data
Nov. 11, 2004 (JP) 2004-327502

(51) Int. Cl. H04B 1/38; H03F 3/38

(52) U.S. Cl. 455/73; 330/10

(57) ABSTRACT

An amplifying circuit which can provide an output signal having less distortion at high power efficiency without increasing the circuit scale and the sizes of the entire device. The amplifying circuit (100) generates two constant envelope signals from an OFDM signal inputted to an S/P converting section (131), and after amplifying each of the constant envelope signals by two amplifiers (111, 112), respectively, the signals are combined by a combiner (113) and a transmission signal is provided. At this time, a pilot signal generating section (102) adds a pilot signal whose frequency orthogonally intersects with that of an OFDM subcarrier to the two constant envelope signals, extracts a pilot signal from the transmission signal of output, and controls a vector adjusting section (105) so that the gains or the phases of the two systems are equivalent.

### TECHNICAL FIELD

The present invention relates to an amplifying circuit or the like for amplifying transmitted signals and particularly relates to a final-stage amplifying circuit for amplifying transmitted signals in a transmitting apparatus that is used in wireless communication and broadcasting employing an orthogonal frequency division multiplexing (OFDM) scheme. The present invention also relates to a radio communication circuit, a radio base station apparatus, and a radio terminal apparatus that are provided with this amplifying circuit.

### BACKGROUND ART

The transmission of digitally modulated signals has become frequent in transmission apparatuses used in wireless communication and transmission in recent years. Most of these digitally modulated signals can carry information in the direction of amplitude due to progress in M-ary, and therefore linearity has been needed in the amplifying circuits used in transmission apparatuses. Meanwhile, high electrical efficiency has also been needed for amplifying circuits in order to reduce the electrical consumption of transmission apparatuses. A variety of methods for compensating for distortion and improving efficiency have been proposed in order to combine both linearity and excellent electrical efficiency in an amplifying circuit. One conventional amplifying circuit scheme is called the LINC (linear amplification with non-linear components) scheme. In the LINC scheme, transmitted signals are bifurcated into two constant envelope signals and combined after being amplified in a non-linear amplifier having high electrical efficiency, whereby improvements in both linearity and electrical efficiency are attained.

FIG. 1 is a diagram that shows a generalized example of the configuration of a conventional amplifying circuit. A general example of an amplifying circuit to which the LINC scheme has been applied will be described using FIG. 1. In amplifying circuit 310 shown in FIG. 1, constant envelope signal generating section 311 generates two constant envelope signals Sa(t) and Sb(t) from input signal S(t). If constant envelope signals Sa(t) and Sb(t) are given by, for example, equations (2) and (3) below when input signal S(t) is given by equation (1), then the amplitude direction of constant envelope signals Sa(t) and Sb(t) is a constant.
S(t)=V(t)×cos{ωct+φ(t)} (Equation 1)
Sa(t)=Vmax/2×cos{ωct+φ(t)} (Equation 2)
Sb(t)=Vmax/2×cos{ωct+θ(t)} (Equation 3)
The maximum value of V(t) is Vmax, the angular frequency of the carrier wave of the input signal is ωc, φ(t)=φ(t)+α(t), and θ(t)=φ(t)−α(t).

FIG. 2 is a diagram that shows the calculation operations of the conventional amplifying circuit shown in FIG. 1 on orthogonal plane coordinates. In other words, FIG. 2 uses signal vectors on orthogonal plane coordinates and show the operations of generating the constant envelope signals. As shown in FIG. 2, input signal S(t) is given by the vector sum of the two constant envelope signals Sa(t) and Sb(t), which have an amplitude of Vmax/2.

Returning again to FIG. 1, two amplifiers 312 and 313 amplify the two constant envelope signals Sa(t) and Sb(t), respectively. If the gain of each amplifier 312 and 313 is G, then the output signals of amplifiers 312 and 313 are G×Sa(t), G×Sb(t), respectively. When these output signals G×Sa(t) and G×Sb(t) are combined in combining circuit 314, output signal G×S(t) is obtained.

FIG. 3 is a diagram that shows another example configuration of a conventional amplifying circuit. Amplifying circuit 310a having the same functions as FIG. 1 will be described using FIG. 3. In constant envelope signal generating section 311, constant envelope signal IQ generating section 315 generates baseband signals Sai and Saq, Sbi and Sbq, which are from baseband input signals Si and Sq and become constant envelope signals Sa and Sb after orthogonal demodulation, are generated by digital signal processing. After the baseband signals are converted to analog signals by D/A converters 316a, 316b, 316c and 316d, the signals are subjected to orthogonal modulation in orthogonal modulating section 317 having two orthogonal modulators, and two constant envelope signals Sa(t) and Sb(t) are obtained. After the signals have been amplified in first-stage amplifiers (driver amps) 318a and 318b, final amplification occurs in final-stage amplifiers 312 and 313. Once the signals are combined in combining circuit 314, output signal G×S(t) is obtained.

In amplifying circuit 310a as above, the generation of constant envelope signals can be implemented by digital signal processing using low-frequency baseband signals, but, when errors occur in the gain or phase of the two amplifier lines, the vector of the signal after amplification and combining is different from the vector of the intended output signal. In other words, these vector errors become distortion components in the output signal. Not only is predicting the causes of these vector errors difficult with amplifying circuit 31a, but the characteristics may also fluctuate depending on the environment including, for example, temperature.

In order to compensate for these distortion components and characteristic fluctuations in conventional amplifying circuits, methods have been proposed (in, for example, patent document 1) in which, for example, an approximation of an auxiliary wave signal is calculated from and combined with the input signal when generating the constant envelope signals. The two constant envelope signals are generated by combining the auxiliary wave signal and the input signal. The constant envelope signals are amplified by two amplifiers, and after combination the output signal or the auxiliary wave component is detected and the characteristic errors in the gain and phase of the two amplifier lines are corrected. Techniques have also been proposed (in, for example, patent document 2) in which the constant envelope signals are generated after orthogonal detection of the transmitted signal. These constant envelope signals are amplified in two amplifier lines and then combined, whereby the distortion components and characteristic fluctuations are compensated for and efficient amplification is performed.
Patent Document 1: Japanese Patent No. 2758682
Patent Document 2: Japanese Patent Application No. 6-22302

### DISCLOSURE OF INVENTION

### Problems to be Solved by the Invention

However, calculation processing must be carried out in order to make a reference to the signal in the aforementioned conventional amplifying circuits, but the analysis of the output signal or auxiliary wave signal, which are of the same band component as the input signal, is also necessary to be logged at that time. The signal band is wide in OFDM schemes in particular, and therefore the required amount and speed of calculation increases. Problems result in that the electricity consumption and circuit size of the amplifying circuit increase.

It is therefore an object of the present invention to provide an amplifying circuit that can minimize increases in circuit size and yield output signals having little distortion at high electrical efficiency, and to provide a radio communication circuit, a radio base station apparatus, and a radio terminal apparatus that are provided with this amplifying circuit.

### Means for Solving the Problem

An amplifying circuit of the present invention adopts a configuration having: an addition section that adds a plurality of pilot signals having a frequency in orthogonal relation to an input signal, to a plurality of constant envelope signals that are generated from the input signal (OFDM signal) subjected to orthogonal frequency division multiplex; an amplification section that amplifies the plurality of constant envelope signals to which the plurality of pilot signals are added by the addition section; a combining section that combines the plurality of constant envelope signals amplified by the amplification section; a detection section that detects pilot signal components from the plurality of constant envelope signals combined by the combining section; and a correction section that corrects at least one of a gain and a phase of any of the plurality of constant envelope signals to which the plurality of pilot signals are added by the addition section so that the pilot signal components detected by the detection section fulfill a predetermined condition.

A TDD (time division duplex) radio communication circuit of the present invention adopts a configuration having: a receiving section that comprises a Fourier transform section that receives a signal that is subjected to orthogonal frequency division multiplex; and a transmitting section that adds, amplifies, and combines an input signal and generates an output signal, wherein the transmitting section has: an addition section that adds a plurality of pilot signals having a frequency in orthogonal relation to the input signal, to a plurality of constant envelope signals generated from the input signal subjected to orthogonal frequency division multiplex; an amplification section that amplifies the plurality of constant envelope signals to which the plurality of pilot signals are added by the addition section; a combining section that combines the plurality of constant envelope signals amplified by the amplification section; and a correction section that detects pilot signal components from the plurality of constant envelope signals combined by the combining section in the Fourier transform section provided in the receiving section, and that corrects at least one of a gain or a phase of any of the plurality of constant envelope signals to which the plurality of pilot signals are added by the addition section so that the detected pilot signal components fulfill a predetermined condition.

### Advantageous Effect of the Invention

According to the present invention, a plurality of pilot signals, which have a frequency that is orthogonal to an input OFDM signal, are added to a plurality of amplified and combined constant envelope signals. The pilot signal components are detected from the plurality of amplified and combined constant envelope signals to which the plurality of pilot signals are added. The gain or phase is also corrected in any of the plurality of constant envelope signals, to which the plurality of pilot signals are added, so that the detected pilot signal components fulfill predetermined conditions. Therefore, when, for example, sine waves are used as the pilot signals, errors in gain or phase in the plurality of lines in the amplifying circuit can be calculated and corrected by comparing the pilot signals. A large scale calculation circuit for error correction is therefore unnecessary, and the circuit size of the amplifying circuit can be reduced. No interference is added to the OFDM signal, and output OFDM signals having little distortion can be obtained at a high electrical efficiency.

According to the present invention, the pilot signals can also be more easily separated and detected by Fourier transformation, and therefore phase errors in the plurality of lines in the amplifying circuit can be corrected using a simple circuit configuration.

According to the present invention, the pilot signals can be more easily separated and detected by Fourier transformation using a Fourier transform section provided to the receiving section. Phase errors in the amplifying circuit that has a plurality of lines and that constitutes the transmitting section of the radio communication circuit can thereby be corrected using a simple circuit configuration.

### BRIEF DESCRIPTION OF DRAWINGS

FIG. 1 is a diagram that shows a generalized example of the configuration of a conventional amplifying circuit;

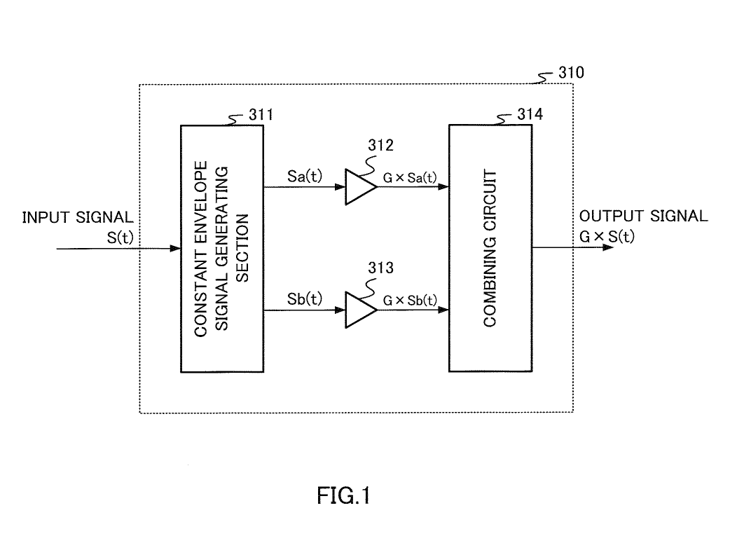

FIG. 2 is a diagram that shows the calculation operations of a conventional amplifying circuit on orthogonal plane coordinates;

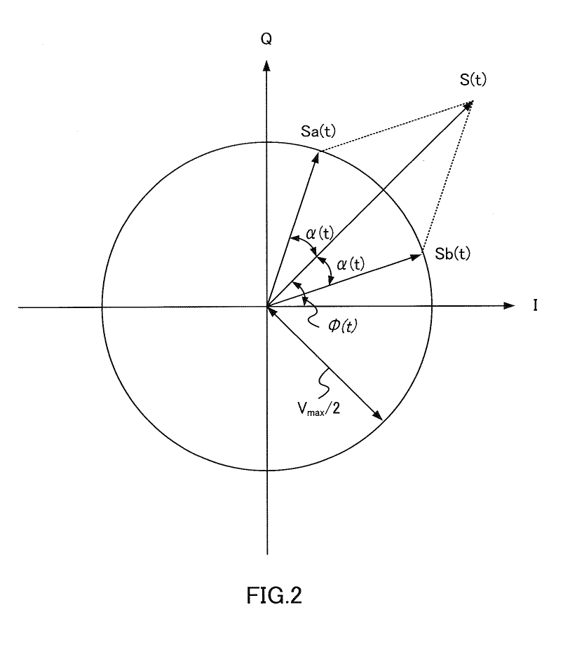

FIG. 3 is a diagram that shows another example configuration of a conventional amplifying circuit;

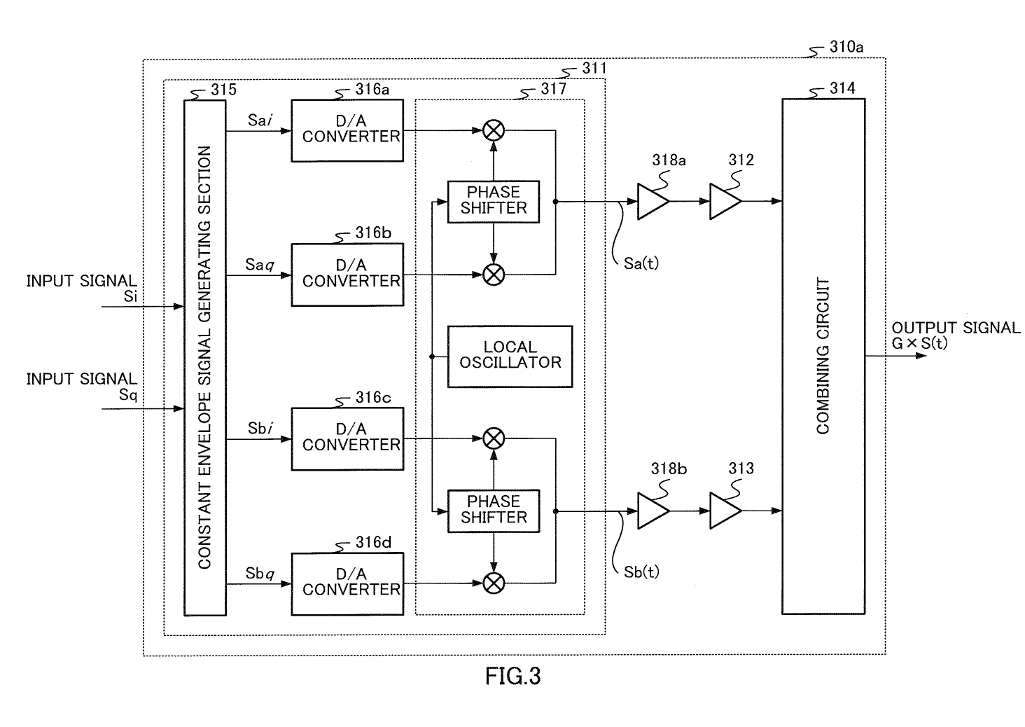

FIG. 4 is a block diagram that shows the configuration of an amplifying circuit according to Embodiment 1 of the present invention;

FIG. 5 is a diagram that shows the calculation operations of Embodiment 1 of the present invention on orthogonal plane coordinates;

FIG. 6 is a diagram that shows the spectrum of the output signal in the amplifying circuit according to Embodiment 1 of the present invention; and

FIG. 7 is a block diagram that shows the configuration of an amplifying circuit according to Embodiment 2 of the present invention.

### BEST MODE FOR CARRYING OUT THE INVENTION

In the amplifying circuit of the present invention, a plurality of pilot signals, which have a frequency that is in orthogonal relation to an OFDM signal, are added to a plurality of amplified and combined constant envelope signals that are generated from the OFDM signal. The desired pilot signal components are detected from the plurality of amplified and combined constant envelope signals to which the plurality of pilot signals are added. Features of the amplifying circuit of the present invention include that at least one parameter selected from the gain and the phase of any of the plurality of constant envelope signals to which the plurality of pilot signals has been added is corrected so that the detected pilot signal components fulfill predetermined conditions Increases in the circuit size of the amplifying circuit can thereby be minimized, and an output signal having little distortion can be obtained at high electrical efficiency.

Now, embodiments of the amplifying circuit of the present invention will be described in detail with reference to the accompanying drawings. The same codes will be applied to components that are the same in the drawings used for each embodiment, and redundant descriptions will omitted to the extent possible.

### Embodiment 1

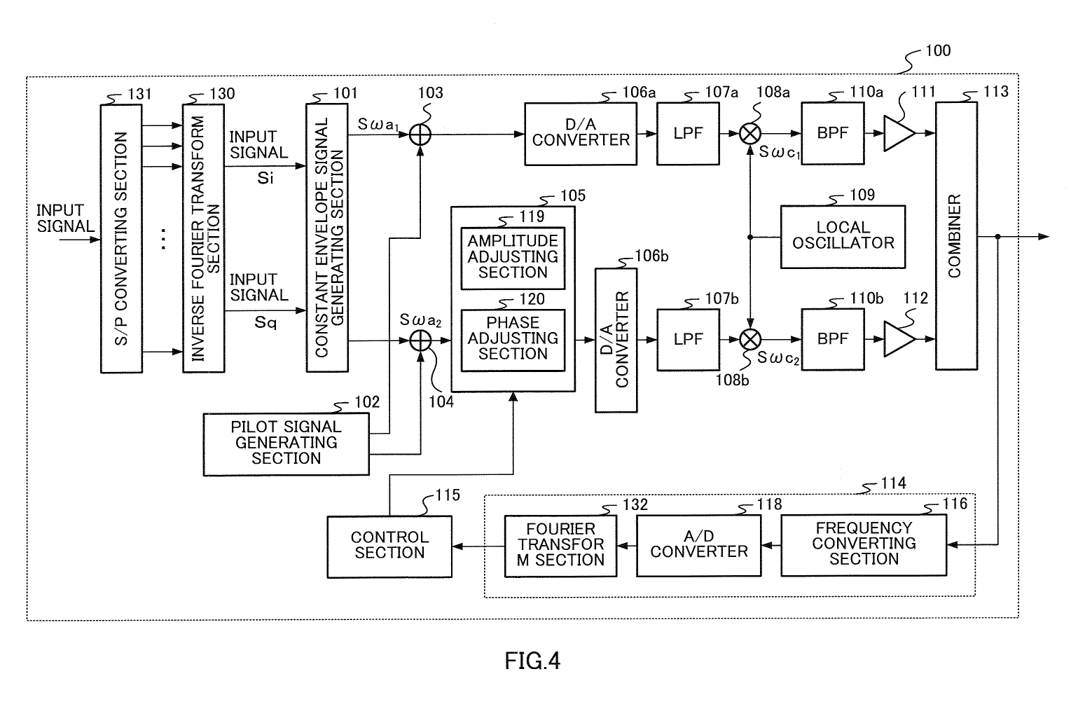

FIG. 4 is a block diagram that shows the configuration of an amplifying circuit according to Embodiment 1 of the present invention. The configuration of amplifying circuit 100 shown in FIG. 4 will be described first. Amplifying circuit (transmitting section) 100 is provided with: S/P converting section 131; inverse Fourier transform section 130; constant envelope signal generating section 101; pilot signal generating section 102; first addition section 103; second addition section 104; vector adjusting section 105; two D/A converters, i.e. 106a and 106b; two LPFs (low-pass filters), i.e. 107a and 107b; two mixers, i.e. 108a and 108b; local oscillator 109; two BPFs (band-pass filters), i.e. 110a and 110b; first amplifier 111; second amplifier 112; combiner 113; pilot signal detecting section 114; and control section 115. Pilot signal detecting section 114 is also provided with frequency converting section 116, A/D converter 118, and Fourier transform section 132. Vector adjusting section 105 is further provided with amplitude adjusting section 119 and phase adjusting section 120.

The functions of the components of amplifying circuit 100 will be described next. S/P converting section 131 converts the fixed time unit of the input signal from serial to parallel, and outputs the result to inverse Fourier transform section 130. Inverse Fourier transform section 130 allocates signals output by S/P converting section 131 to orthogonal frequencies (that is, OFDM subcarriers), performs inverse Fourier transform and orthogonal modulation on the signals, and outputs baseband signals Si and Sq that constitute an OFDM signal.

Constant envelope signal generating section 101 uses the input baseband signals Si and Sq, combines vectors, and generates and outputs two constant envelope signals that is equivalent to signals resulting from orthogonal modulation of baseband signals Si and Sq using a carrier-wave frequency that has a frequency ωa. That is, constant envelope signal generating section 101 generates first constant envelope signal Sωa₁ and second constant envelope signal Sωa₂ from the input baseband signals Si and Sq and outputs the result to first addition section 103 and second addition section 104, respectively.

Pilot signal generating section 102 generates two pilot signals that have frequencies in orthogonal relation to the OFDM subcarriers of the OFDM signal resulting from orthogonal modulation of the frequencies of baseband signals Si and Sq. The two pilot signals are output to first addition section 103 and second addition section 104, respectively. That is, pilot signal generating section 102 generates a first pilot signal and a second pilot signal and outputs these signals to first addition section 103 and second addition section 104, respectively.

First addition section 103 adds together the input first constant envelope signal Sωa₁ and first pilot signal. Second addition section 104 adds together the input second constant envelope signal Sωa₂ and second pilot signal.

Vector adjusting section 105 is, for example, a calculation circuit that is controlled by control section 115 (described hereinafter) to change the gain and phase of the signal output from second addition section 104, and outputs the result to D/A converter 106b. To be more specific, amplitude adjusting section 119 of vector adjusting section 105 is controlled by control section 115 to adjust the gain (the direction of amplitude) of the signal output from second addition section 104, and phase adjusting section 120 is controlled by control section 115 to adjust the phase (the direction of phase) of the signal output from second addition section 104.

S/P converting section 131, inverse Fourier transform section 130, constant envelope signal generating section 101, pilot signal generating section 102, first addition section 103, second addition section 104, and vector adjusting section 105 in this case are, for example, digital signal-processing circuits that are configured with a DSP (digital signal processor), CPU (central processing unit), ASIC (application-specific integrated circuit), or the like, with respective functions being performed by calculating digital signals.

D/A converter 106a converts first constant envelope signal Sωa₁, to which the first pilot signal is added by first addition section 103, from a digital value to an analog value. D/A converter 106b converts second constant envelope signal Sωa₂, which is output from vector adjusting section 105 and to which the second pilot signal is added, from a digital value to an analog value.

LPFs 107a and 107b remove sampling frequencies and folding noise components from the signals output from D/A converters 106a and 106b, and output first constant envelope signal Sωa₁ and second constant envelope signal Sωa₂ to mixers 108a and 108b, respectively. Mixers 108a and 108b are, for example, mixer circuits for upconverting frequencies. Mixers 108a and 108b mix the signals output from LPFs 107a and 107b with a local oscillating signal from local oscillator 109 and convert (upconvert) the frequencies of the mixed first constant envelope signal Sωc₁ and second constant envelope signal Sωc₂ into predetermined respective frequencies for the output signal use.

Local oscillator 109 is, for example, a frequency combiner that uses a voltage controlled oscillator (VCO) that is controlled by a phase locked loop (PLL). Local oscillator 109 outputs a local oscillating signal to mixers 108a and 108b.

BPFs 110a and 110b are filters that pass signals of a predetermined frequency band and suppress unnecessary frequency components. BPFs 110a and 110b suppress unnecessary frequency components that are included in first constant envelope signal Sωa₁ and second constant envelope signal Sωa₂, which are subjected to up-conversion by mixers 108a and 108b. In other words, BPFs 110a and 110b suppress the image components that occur in mixers 108a and 108b and leaked components of the local oscillating signal, and output the suppressed first constant envelope signal Sωc₁ and second constant envelope signal Sωc₂ to first amplifier 111 and second amplifier 112, respectively.

First amplifier 111 amplifies the signal output from BPF 110a and outputs the result to combiner 113. Second amplifier 112 amplifies the signal output from BPF 110b and outputs the result to combiner 113. Combiner 113 is, for example, a combining section that can be implemented as a four-terminal directional coupler in which a distributed constant circuit is used or a Wilkinson combiner, combines the signals amplified by first amplifier 111 and second amplifier 112 and obtains the output signal of amplifying circuit 100.

Pilot signal detecting section 114 extracts the pilot signal components from part of the signal output from combiner 113 and outputs the components to control section 115. A component equivalent to the first pilot signal and a component equivalent to the second pilot signal are included in the pilot signal components at this point. To be more specific, frequency converting section 116 of pilot signal detecting section 114 converts the frequency of the OFDM signal obtained from combiner 113 and including the pilot signals, to a low-frequency band and outputs the result to A/D converter 118. A/D converter 118 converts the OFDM signal including the pilot signals, from analog to digital and outputs the result to Fourier transform section 132. Fourier transform section 132 performs a Fourier transform on the OFDM signal including the pilot signals, and separates the signals per OFDM subcarrier from the pilot signal components orthogonal to the OFDM subcarriers, and outputs the separated pilot signal components to control section 115.

Control section 115 is configured with, for example, a CPU, DSP, ASIC or other calculation circuit, and a memory, and controls the adjustment of gain and phase in vector adjusting section 105 on the basis of the pilot signal components (that is, the first pilot signal component and the second pilot signal component) that are output by pilot signal detecting section 114. To be more specific, if the amount of adjustment in the directions of amplitude and phase in vector adjusting section 105 are designated as γ and β, respectively, then control section 115 sets the value of the adjustment amount γ in the direction of amplitude so that the amplitude components of the first pilot signal component and the second pilot signal component detected by pilot signal detecting section 114, are both equal. Control section 115 also sets the value of the adjustment amount β in the direction of phase so that the phase components of the first pilot signal component and the second pilot signal component detected by pilot signal detecting section 114, are both equal.

The operations of amplifying circuit 100 configured as above will be described next using FIG. 4. First, in S/P converting section 131, data of the input signal in a predetermined unit of time Ts for a single OFDM symbol, is converted by from serial to parallel and is output to inverse Fourier transform section 130. Inverse Fourier transform section 130 allocates signals output by S/P converting section 131 to frequencies (OFDM subcarriers) having frequency interval Δfs (=1/Ts) performs inverse Fourier transform and orthogonal modulation on the signals, and outputs baseband signals Si and Sq that constitute an OFDM signal.

Constant envelope signal generating section 101 then generates first constant envelope signal Sωa₁(t) and second constant envelope signal Sωa₂(t) from the baseband input signals Si and Sq. If signal Sωa(t) obtained by orthogonal modulation on the input signals Si and Sq using the carrier frequency of angular frequency ωa, is given by equation (4), and if first constant envelope signal Sωa₁(t) and second constant envelope signal Sωa₂(t) are given by equations (5) and (6), then first constant envelope signal Sωa₁(t) and second constant envelope signal Sωa₂(t) will be constant envelope signals for which the direction of amplitude is a constant.
Sωa(t)=V(t)×cos{ωat+φ(t)} (Equation 4)
Sωa₁(t)=Vmax/2×cos{ωat+φ(t)} (Equation 5)
Sωa₂(t)=Vmax/2×cos{ωat+θ(t)} (Equation 6)
The maximum value of V(t) is Vmax, φ(t)=φ(t)+α(t), and θ(t)=φ(t)−α(t).

The first pilot signal and the second pilot signal, generated at pilot signal generating section 102, are sine waves that both have an amplitude of P and that have frequencies of (ωa−ωp₁) and (ωa−ωp₂), respectively. In other words, first pilot signal P₁(t) and second pilot signal P₂(t) are given by P₁(t)=P×cos{(ωa−ωp₁)t} and P₂(t)=P×cos{(ωa−ωp₂)t}, respectively. Signals S′ωa₁(t), S′ωa₂(t) output by first addition section 103 and second addition section 104 are given by equations (7) and (8), respectively, in such instances.
S′ωa₁(t)=Sωa₁(t)+P₁(t)=Vmax/2×cos{ωat+φ(t)}+P×cos{(ωa−ωp₁)t} (Equation 7)
S′ωa₂(t)=Sωa₂(t)+P₂(t)=Vmax/2×cos{ωat+θ(t)}+P×cos{(ωa−ωp₂)t} (Equation 8)

The first pilot signal and the second pilot signal have an orthogonal relation to the subcarriers of the OFDM signal at this point. The angular frequencies (ωa−ωp₁)/2π and (ωa−ωp₂)/2π are in detuning relation to the OFDM subcarriers by an integral multiple of Δfs.

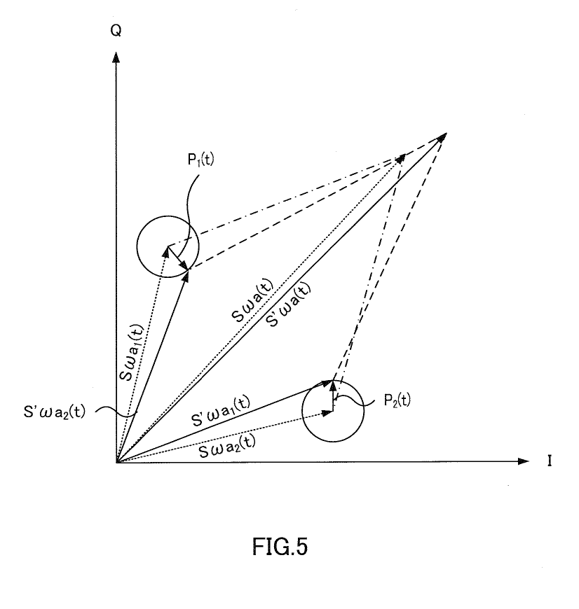

FIG. 5 is a diagram that shows the calculation operations of Embodiment 1 of the present invention on orthogonal plane coordinates. In other words, FIG. 5 shows the calculation operations given by equations (4) through (8) using signal vectors on orthogonal plane coordinates. As shown in FIG. 5, S′ωa₁(t) and S′ωa₂(t) result from adding P₁(t) and P₂(t) to first constant envelope signal Sωa₁(t) and second constant envelope signal Sωa₂(t), which both have an amplitude of Vmax, respectively. The combination of these signals is S′ωa(t).

Returning again to FIG. 4, vector adjusting section 105 is controlled by control section 115 to adjust signal S′ωa₂(t) output by second addition section 104, by, for example, γ times in the direction of amplitude and by amount of phase shift β in the direction of phase. Signal Soutv(t) output from vector adjusting section 105 at this point, can be given by equation (9).
Soutv(t)=γ×[Vmax/2×cos{ωat+θ(t)+β}+P×cos{ωa−ωp₂}t+β (Equation 9)

D/A converter 106a converts signal S′ωa₁(t) output from first addition section 103, to an analog signal, and D/A converter 106b converts signal Soutv(t) output from vector adjusting section 105, to an analog signal. LPFs 107a and 107b then suppress folding noise components in the signals that have been converted from digital to analog and output from D/A converter 106a and D/A converter 106b, respectively.

Mixers 108a and 108b convert the carrier frequencies of the signals where noise components are suppressed, to ωc. BPFs 110a and 110b then suppress image components that may occur in mixers 108a and 108b, leaked components of the local oscillating signal, and other unnecessary spurious components in the frequency-converted signals. First amplifier 111 then amplifies the signal output from BPF 110a, and second amplifier 112 amplifies the signal output from BPF 110b.

First amplifier 111 and second amplifier 112 amplify the signals where the constant envelope signals are subjected to frequency conversion to angular frequency ωc and the pilot signals are added thereto. The signals amplified by first amplifier 111 and second amplifier 112 are therefore not entirely constant envelope signals, but if the amplitude of the pilot signals is made adequately small relative to the constant envelope signals, envelope fluctuations in the amplified signals at this point can be made extremely small. If the level of the pilot signals is set at, for example, 40 dB, which is lower than the level of the constant envelope signals, then the amplitude of envelope fluctuations in the amplified signals is approximately 1%. First amplifier 111 and second amplifier 112 can therefore be used at high electrical efficiency. Combiner 113 then combines the signals output from first amplifier 111 and second amplifier 112. The output signals having little distortion at high electrical efficiency can thus be obtained from amplifying circuit 100.

If the gain and amount of phase shift from D/A converter 106a to first amplifier 111 at this point are Ga and Ha, respectively, and the gain and amount of phase shift from D/A converter 106b to second amplifier 112 are Gb and Hb, respectively, then signal Souta₁ output from first amplifier 111, and signal Souta₂ output from second amplifier 112, are given by equations (10) and (11), respectively.
Souta₁=Ga×[Vmax/2×cos{ωct+φ(t)+Ha}+P×cos{(ωc−ωp₁)t+Ha} (Equation 10)
Souta₂=Gb×γ×[Vmax/2×cos{ωct+θ(t)+β+Hb}+P×cos{(ωc−ωp₂)t+β+Hb}] (Equation 11)

Signal S′(t) output from combiner 113 is therefore a signal resulting from the in-phase addition of the two signals given by equations (10) and (11) and can therefore be given by the following equation (12).
S′(t)=Ga×[Vmax/2×cos{ωct+φ(t)+Ha}+Gb×γ×[Vmax/2×cos{ωct+θ(t)+β+Hb}+Ga×P×cos{ωc−ωp₁)t+Ha}+Gb×γ×P×cos{(ωc−ωp₂)t+β+Hb} (Equation 12)

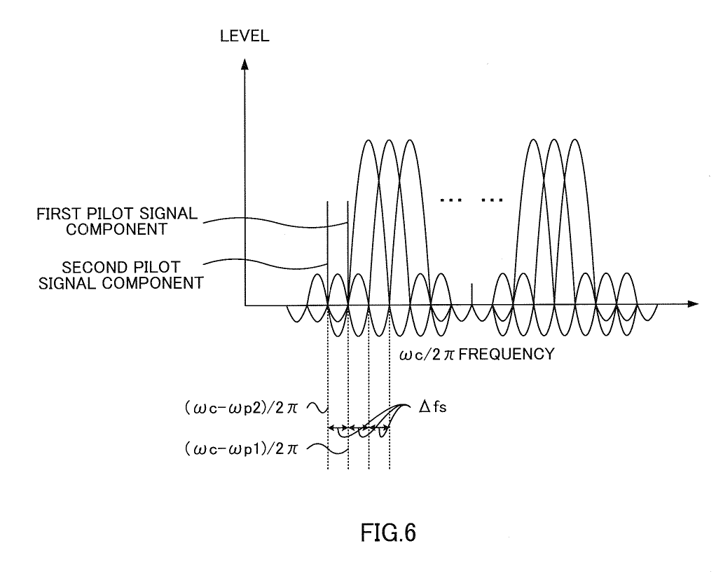

FIG. 6 is a diagram that shows the spectrum of the output signal in the amplifying circuit according to Embodiment 1 of the present invention. In other words, FIG. 6 shows the spectrum of the signal output from amplifying circuit 100 of Embodiment 1 shown in FIG. 4. The horizontal axis in FIG. 6 designates frequency, and the vertical axis designates the signal level. The orthogonal frequency relationship between the added pilot signal components and the OFDM signal is easily understood from FIG. 6.

If Ga=Gb×γ and Ha=Hb+β at this point, then the first and second terms on the right-hand side of equation (12) when combination is performed are similar to equations (2) and (3) that give the constant envelope signals that become equation (1). Equation (12) can therefore be converted into the following equation (13).
S′(t)=Ga×V(t)×cos{ωct+φ(t)+Ha}+Ga×P×cos{(ωc−ωp₁)t+Ha}+Ga×P×cos{(ωc−ωp₂)t+Ha} (Equation 13)

The first term on the right-hand side of equation (13) is a signal that results from the input signal subjected to orthogonal modulation using a carrier wave of angular frequency ωc and subjected to phase shift in the gain by Ga times and in the phase by Ha—that is, the desired wave signal component amplified by gain Ga.

In other words, part of the output signal of amplifying circuit 100 in Embodiment 1 is extracted and input to pilot signal detecting section 114. The pilot signal components that are given by the third and fourth terms on the right-hand side of equation (12) are detected by pilot signal detecting section 114, and control section 115 controls vector adjusting section 105 so that Ga=Gb×γ and Ha=Hb+β.

Frequency converting section 116 of pilot signal detecting section 114 converts the output signal to a lo frequency band that can be converted from analog to digital by A/D converter 118. A/D converter 118 and Fourier transform section 132 perform the general demodulation operations on the OFDM signal. In other words, A/D converter 118 samples the analog signal of the OFDM signal including the first pilot signal and the second pilot signal, at a sampling interval of Ts/N (N is generally a power-of-two number) and converts the OFDM signal to a digital signal. Fourier transform section 132 performs a Fourier transform on the digital signal output from A/D converter 118, thereby obtaining Δfs interval data.

The first pilot signal and the second pilot signal are in detuning relation to the OFDM subcarriers by an integral multiple of Δfs. Fourier transform section 132 therefore separates the pilot signals from the OFDM signal using the above-described OFDM demodulation process and outputs the result to control section 115. In other words, the components of the third and fourth terms on the right-hand side of equation (12) can both be extracted, and therefore the values of Ga×P, Ha, Gb×γ×P, and β+Hb can be known.

Control section 115 then controls the adjustment of gain γ and amount of phase shift β in vector adjusting section 105 so that the amplitude components Ga×P and Gb×γ×P as well as the phase components Ha and β+Hb are equal in the pilot signal components. In other words, the signal given by equation (13) can be obtained as the output signal of amplifying circuit 100 using this operation.

Even if, for example, the bandwidth of the signal subjected to OFDM modulation at this point is a broadband of several MHz or more, the pilot signal components are signals sampled at Ts=1/Δfs. Therefore, control section 115 can perform calculation processing to adjust the amplitude and phase components in frequencies that are adequately low compared to the bandwidth of the signal. In receivers for receiving the OFDM signals to which these pilot signals have been added, the operations similar to the aforedescribed operations of pilot signal detecting section 114 are performed and the pilot signals can be separated in the receiver, so that the pilot signals are not interference components.

According to the amplifying circuit of Embodiment 1 of the present invention, errors in gains and phases in the two lines of the LINC amplifying circuit 100 that amplifies OFDM signals are thus calculated in control section 115 via a comparison of the pilot signals having frequencies in orthogonal relation to the subcarriers of the OFDM signal. Adjustment (correction) of the amplitude and phase components is performed in vector adjusting section 105 on the basis of the calculated errors in gain and phase, and therefore a large-size calculation circuit is not necessary for corrections, and the circuit size of amplifying circuit 100 can be reduced. Output OFDM signal S′(t) can be obtained having little distortion at high electrical efficiency without adding interference to the OFDM signal.

In the description above, combiner 113 is assumed to be an ideal in-phase combiner, but according to the amplifying circuit of Embodiment 1, the differences in gain and phase can be corrected even if these difference components are present in combiner 113 during combination. Additionally, the gain and phase are corrected in vector adjusting section 105 in the description above, but the same operational effects can be obtained using a variable gain amplifier, variable phase shifter, or another apparatus that uses an analog circuit. Electrical efficiency can be further improved if, for example, a configuration is adopted where the bias of first amplifier 111 and second amplifier 112 is controlled as a variable gain configuration.

Phase adjusting section 120 has been used as a variable phase shifting section in the description above, but when phase errors are largely caused by differences in the amount of delay, the same operational effects as above can also be obtained using a variable delay section. An in-phase combiner 113 has been also used in the description above, but combiner 113 is not limited to these phase characteristics. As long as the amount of phase shift is taken into consideration when generating the constant envelope signals, the same operational effects as the above can also be obtained when using, for example, a directional coupler that shifts phase 90 degrees and combines the result, instead of combiner 113.

The pilot signals in the description above have been sine waves, but the same operational effects as above can also be obtained with modulated waves as long as the symbol interval of the modulated waves is Ts. The first pilot signal and the second pilot signal also have different frequencies in the description above, but even when the frequencies are made to be the same, and when the pilot signals have amplitudes and phases that cancel each other out in the output of combiner 113, providing that there are no gain or phase errors in the two lines of amplifying circuit 100, an effect of reduced pilot signal radiation levels can be expected in addition to the operational effects above.

### Embodiment 2

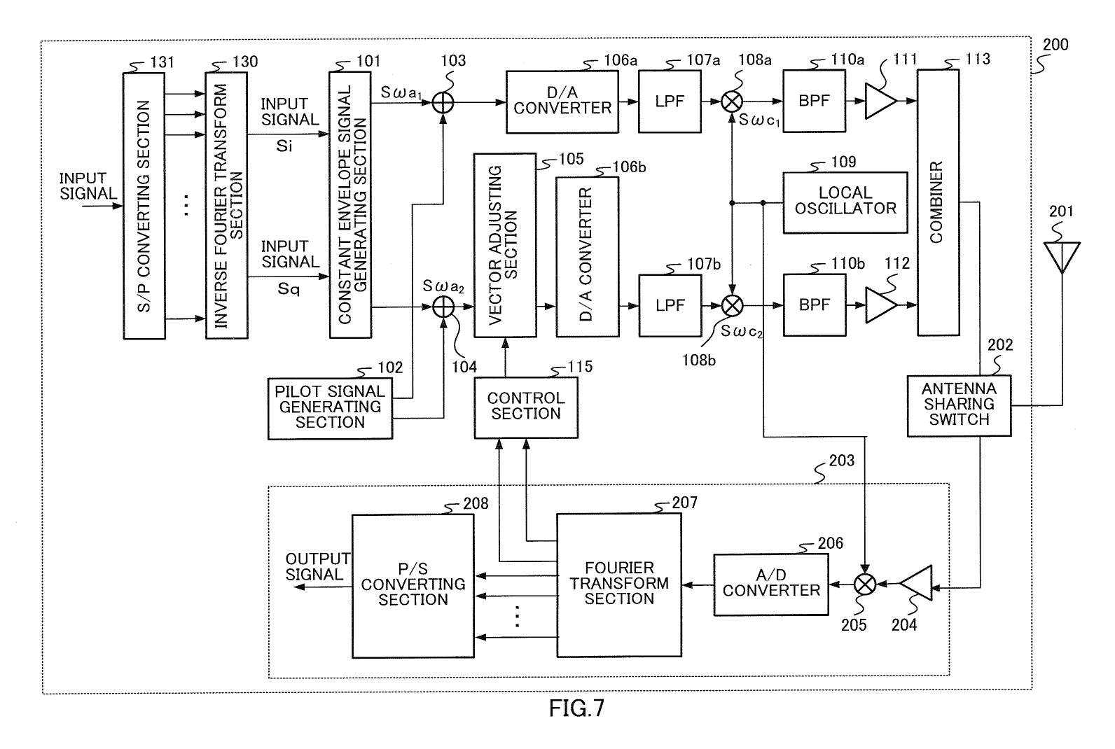

FIG. 7 is a block diagram that shows the configuration of an amplifying circuit according to Embodiment 2 of the present invention. The configuration of radio-transmitting and receiving apparatus 200 shown in FIG. 7 will be described first. Radio-transmitting and receiving apparatus (radio communication circuit) 200 is provided with: S/P converting section 131; inverse Fourier transform section 130; constant envelope signal generating section 101; pilot signal generating section 102; first addition section 103; second addition section 104; vector adjusting section 105; two D/A converters, i.e. 106a and 106b; two LPFs, i.e. 107a and 107b; two mixers, i.e. 108a and 108b; local oscillator 109; two BPFs, i.e. 110a and 110b; first amplifier 111; second amplifier 112; combiner 113; antenna sharing switch 202; antenna 201; radio receiving section (receiving section) 203; and control section 115. Radio receiving section 203 is also provided with low noise amplifier 204, reception mixer 205, A/D converter 206, Fourier transform section 207, and P/S converting section 208.

The functions of the elements of radio transmitting and receiving apparatus 200 shown in FIG. 7 will be described next. The operations of S/P converting section 131, inverse Fourier transform section 130, constant envelope signal generating section 101, pilot signal generating section 102, first addition section 103, second addition section 104, vector adjusting section 105, two D/A converters 106a and 106b, two LPFs 107a and 107b, two mixers 108a and 108b, local oscillator 109, two BPFs 110a and 110b, first amplifier 111, second amplifier 112, and combiner 113 are to the same as the operations described in Embodiment 1. Combiner 113 outputs an OFDM signal that includes pilot signals.

Antenna 201 is an antenna that transmits and receives radio signals and is used for both transmission and reception. Antenna sharing switch 202 switches antenna 201 between transmission and reception at a given time.

Radio receiving section 203 amplifies the received radio signal using low noise amplifier 204 and converts the frequency of the radio signal using reception mixer 205. The analog signal is then converted to a digital signal in A/D converter 206, subjected to a Fourier transformation in Fourier transform section 207, and converted from parallel to serial in P/S converting section 208 to obtain the received signal.

Radio transmitting and receiving apparatus 200 is a TDD radio transmitting and receiving apparatus. During transmission, antenna sharing switch 202 is switched to transmission and no signals are received. However, antenna sharing switch 202 is configured using general semiconductors, and therefore has leakage. In other words, the OFDM signal to be transmitted, which includes the pilot signals, leaks and is input to radio receiving section 203.

Radio receiving section 203 is a receiving circuit that receives OFDM. The OFDM signal including the pilot signals that leaked in the same manner as in pilot signal detecting section 114 described in Embodiment 1 is subjected to a Fourier transform, and the separated pilot signals can be output to control section 115. According to Embodiment 2, radio transmitting and receiving apparatus 200 transmitting and receiving OFDM signals using a TDD scheme, uses a Fourier transform section provided in the receiving section and separates and detects pilot signals by Fourier transformation for calculating gain and phase errors in the two lines of the LINC amplifier that amplifies the transmission OFDM signal, so that the apparatus size can be reduced and distortion components included in the transmitted signals can be reduced at a low manufacturing cost.

Radio transmitting and receiving apparatus 200 adopts a configuration that shares not only the local oscillating signal output by local oscillator 109 provided in the amplifying circuit, at the mixer of radio receiving section 203, but also control section 115 provided in the amplifying circuit for control at radio receiving section 203 (controlling, for example, automatic gain). The apparatus size of radio transmitting and receiving apparatus 200 can therefore be further reduced.

According to Embodiment 2, the operational effects the same as described in Embodiment 1 can thus be implemented in radio transmitting and receiving apparatus 200, and the apparatus size of radio transmitting and receiving apparatus 200 can be further reduced. Distortion components included in the transmitted signals can thereby be minimized to a level that does not impair communication, and error-free data can be received by the receiver, all at a low manufacturing cost. Radio transmitting and receiving apparatus 200 as described in Embodiment 2 can also be applied to radio base station apparatuses or communication terminal apparatuses that are used in networks for wireless communication and broadcasting.

The present application is based on Japanese Patent Application No. 2004-327502, filed on Nov. 11, 2004, the entire content of which is expressly incorporated by reference herein.

### INDUSTRIAL APPLICABILITY

The amplifying circuit of the present invention can yield output signals having little distortion at high electrical efficiency and enable the circuit size to be minimized, and can therefore be used effectively as a final-stage amplifying circuit for amplifying transmission signals in transmitting apparatuses used in radio communication apparatuses, broadcasting equipment, or the like.

1. An amplifying circuit, comprising:
an addition section that adds a plurality of pilot signals having a frequency in orthogonal relation to an input signal, to a plurality of constant envelope signals that are generated from the input signal subjected to orthogonal frequency division multiplex;
an amplification section that amplifies the plurality of constant envelope signals to which the plurality of pilot signals are added by the addition section;
a combining section that combines the plurality of constant envelope signals amplified by the amplification section;
a detection section that detects pilot signal components from the plurality of constant envelope signals combined by the combining section; and
a correction section that corrects at least one of a gain and a phase of any of the plurality of constant envelope signals to which the plurality of pilot signals are added by the addition section so that the pilot signal components detected by the detection section fulfill a predetermined condition.

2. The amplifying circuit according to claim 1, wherein the correction section corrects the gain so that amplitude components of the pilot signal components are equal.

3. The amplifying circuit according to claim 1, wherein the correction section corrects the phase so that phase components of the pilot signal components are equal.

4. The amplifying circuit according to claim 1, wherein the detection section comprises a Fourier transform section that performs a Fourier transform calculation on a signal subjected to orthogonal frequency division multiplex.

5. A TDD radio communication circuit comprising:
a receiving section that comprises a Fourier transform section that receives a signal that is subjected to orthogonal frequency division multiplex; and
a transmitting section that adds, amplifies, and combines an input signal and generates an output signal, wherein,
the transmitting section has:
an addition section that adds a plurality of pilot signals having a frequency in orthogonal relation to the input signal, to a plurality of constant envelope signals generated from the input signal subjected to orthogonal frequency division multiplex;
an amplification section that amplifies the plurality of constant envelope signals to which the plurality of pilot signals are added by the addition section;
a combining section that combines the plurality of constant envelope signals amplified by the amplification section; and
a correction section that detects pilot signal components from the plurality of constant envelope signals combined by the combining section in the Fourier transform section provided in the receiving section, and that corrects at least one of a gain or a phase of any of the plurality of constant envelope signals to which the plurality of pilot signals are added by the addition section so that the detected pilot signal components fulfill a predetermined condition.
